(19) United States
(12) Patent Application Publication
(10) Pub. No.: US 2025/0253228 A1
(43) Pub. Date: Aug. 7, 2025

(54) POWER MODULE

(71) Applicant: Delta Electronics, Inc., Taoyuan City (TW)

(72) Inventors: HAN LIN WU, Taoyuan City (TW); WEN SHANG LAI, Taoyuan City (TW)

(21) Appl. No.: 18/964,474

(22) Filed: Dec. 1, 2024

(30) Foreign Application Priority Data
Feb. 2, 2024 (CN) 202410153572.7

(51) Int. Cl. H01L 23/498; G01R 19/00; H01L 23/31

(52) U.S. Cl. CPC H01L 23/49861; H01L 23/3107; H01L 23/49838; G01R 19/0092

(57) ABSTRACT

A power module, includes a leadless frame substrate including a first metal layer and an insulating layer, wherein the first metal layer forms a circuit trace disposed on the insulating layer and the first metal layer has an extension structure extending out of the insulating layer to serve as an output terminal; at least one semiconductor power device disposed on the first metal layer; a current detector disposed on the output terminal; and a molding compound, completely covering the first metal layer on the insulating layer of the leadless frame substrate and the at least one semiconductor power device, and partially covering the output terminal so that the current detector is completely disposed outside the molding compound.

### FIELD

The present disclosure relates to power module, and more particularly, to a power module with a current detector.

### BACKGROUND

In an application of existing circuit systems, when the power module is operating, it is necessary to monitor output/input current of the power module. One solution is to attach an external current detection device to an output terminal of the power module. For example, use a plastic frame or a circuit board to fix the current detection device on a lead frame or a bus bar of the output terminal of the power module.

For users, it takes a long time to correct the signal of the current detection device after installing the current detection device. For example, every time a power equipment assembly manufacturer in downstream industry installs a current detection device on a power module. The positioning error of the current detection device after each installation is relatively large because the current detection device is installed or assembled manually. The signal variation between the current detection devices of each power module is large, so the signal needs to be corrected after installation, which is quite time-consuming. A common installation method of current detection devices is to set the current detection devices on a circuit board, then fix the circuit board with output pins of the power module and use U-shaped rings to strengthen magnetic lines to improve signal strength. However, the issue of signal variation caused by inaccurate positioning has not been solved, and assembly of the U-shaped ring is complicated and takes up more space.

### SUMMARY

In view of the above, the present disclosure provides a power module to effectively solve the issue of positioning accuracy of current detector in the prior art.

In order to achieve above-mentioned object of the present disclosure, one embodiment of the disclosure provides a power module, including: a leadless frame substrate, at least one semiconductor power device, a current detector disposed on the output terminal, and a molding compound. The leadless frame substrate includes a first metal layer and an insulating layer, wherein the first metal layer forms a circuit trace disposed on the insulating layer and the first metal layer includes an extension structure extending out of the insulating layer to serve as an output terminal. The at least one semiconductor power device is disposed on the first metal layer. The current detector is disposed on the output terminal. The molding compound completely covers part of the first metal layer disposed on the insulating layer and the at least one semiconductor power device, and partially covers the output terminal so that the current detector is completely disposed outside the molding compound, wherein the power module is configured to convert a direct current power to an alternating current power, to output the alternating current power through the output terminal, and to detect the alternating current power by the current detector.

In one embodiment of the power module, a magnetic susceptibility of the first metal layer is less than 1 and greater than 0.

In one embodiment of the power module, the leadless frame substrate further includes a second metal layer disposed under the insulating layer and the molding compound partially covers the second metal layer.

In one embodiment of the power module, the current detector is disposed on the output terminal with an assistance of a robot arm.

another embodiment of the disclosure provides a power module, including: a leadless frame substrate, at least one semiconductor power device, a current detector, and a molding compound. The leadless frame substrate includes a first metal layer and an insulating layer, wherein the first metal layer forms a circuit trace disposed on the insulating layer and including an output terminal. The at least one semiconductor power device is disposed on the circuit trace. The current detector is disposed on the output terminal. The molding compound completely covers the first metal layer of the leadless frame substrate, the at least one semiconductor power device, and the current detector, wherein the power module is configured to convert a direct current power to an alternating current power, to output the alternating current power through the output terminal, and to detect the alternating current power by the current detector.

In one embodiment of the power module, a magnetic susceptibility of the first metal layer is less than 1 and greater than 0.

In one embodiment of the power module, the leadless frame substrate further includes a second metal layer disposed under the insulating layer and the molding compound partially covers the second metal layer.

In one embodiment of the power module, the current detector is disposed on the output terminal with an assistance of a robot arm.

In one embodiment of the disclosure, the power module further includes a lead frame connected to the output terminal.

In one embodiment of the disclosure, the power module further includes a pin structure disposed on the first metal layer, wherein the current detector is of a surface mount device and a signal end of the current detector is electrically connected to the pin structure through the circuit trace.

In one embodiment of the power module, a signal end of the current detector is electrically connected to the first metal layer through a bonding wire.

In one embodiment of the disclosure, the power module further includes a multilayer substrate circuit structure disposed on the first metal layer.

In one embodiment of the power module, the multilayer substrate circuit structure extends outside the molding compound and a signal end of the current detector is electrically connected to the multilayer substrate circuit structure through a bonding wire.

In one embodiment of the disclosure, the power module further includes a pin structure disposed on the multilayer substrate circuit structure, wherein a signal end of the current detector is electrically connected to the multilayer substrate circuit structure through bonding wire and is further electrically connected to the pin structure through the multilayer substrate circuit structure.

In comparison with prior art, the disclosed structure of the power module is suitable for precise packaging technologies such as surface mount technology (SMT), which can accurately install the current detector at the output terminal to provide a power module with a current detector. Because the positioning error of the current detector disclosed in the present disclosure is small, an initial calibration data of the sensing signal can be directly applied to each power module, and there is no need to recalibrate the signal of the current detector of each power module to effectively avoid the issue in the prior art.

### BRIEF DESCRIPTION OF DRAWINGS

FIG. 1 is a schematic view of a structure of a power module of prior art;

FIG. 2A is a schematic view of a structure of a power module according to a first embodiment of the disclosure;

FIG. 2B is a schematic cross-sectional view of a structure of a power module according to FIG. 2A alone line BB′;

FIG. 3 is a schematic view of a structure of a power module according to a second embodiment of the disclosure;

FIG. 4 is a schematic cross-sectional view of a structure of a power module according to FIG. 3 alone line CC′;

FIG. 5 is a schematic view of a structure of a power module according to a third embodiment of the disclosure;

FIG. 6 is a schematic cross-sectional view of a structure of a power module according to FIG. 5 alone line DD′;

FIG. 7 is a schematic cross-sectional view of a structure of a power module according to FIG. 5 alone line EE′;

FIG. 8 is a schematic view of a structure of a power module according to a fourth embodiment of the disclosure;

FIG. 9 is a schematic view of a structure of a power module according to a fifth embodiment of the disclosure;

FIG. 10 is a schematic cross-sectional view of a structure of a power module according to FIG. 9 alone line FF′;

FIG. 11 is a schematic cross-sectional view of a structure of a power module according to FIG. 9 alone line GG′;

FIG. 12 is a schematic view of a structure of a power module according to a sixth embodiment of the disclosure.

### REFERENCE NUMERALS DESCRIPTION

100, 200, 200′, 200″, 220, 240: power module; 10: leadless frame substrate; 12: first metal layer; 121: input terminal; 122: extension structure; 123, 124: circuit trace; 14: insulating layer; 15: signal pin; 16: output terminal; 18: second metal layer; 20: semiconductor power device; 30: current detector; 32: bonding wire; 40 molding compound; 60: multilayer substrate circuit structure; 62: metal layer; 64: ceramics layer; 70: pin structure; 80: circuit board; 82: fixing hole; BB′, CC′, DD′, EE′, FF′, GG′: line; p10: lead frame; p100: power module; p12: circuit trace; p121: input terminal; p122: extension structure; p16: output terminal; p18: heatsink block; p20: semiconductor power device; p30: current detector; p40: molding compound.

### DETAILED DESCRIPTION

In order to make the above and other objects, features, and advantages of the present disclosure more obvious and understandable, preferred embodiments of the present disclosure will be cited below, together with the drawings, for a detailed description as follows. Furthermore, the direction terms mentioned in this disclosure, such as up, down, top, bottom, front, back, left, right, inside, outside, side layer, surrounding, center, horizontal, transverse, vertical, longitudinal, axial, radial direction, the uppermost layer, or the lowermost layer, etc., are only directions for referring to the attached drawings. Therefore, the directional terms are used to explain and understand the present disclosure, but not to limit the present disclosure. In the figures, structurally similar units are denoted by the same reference numerals.

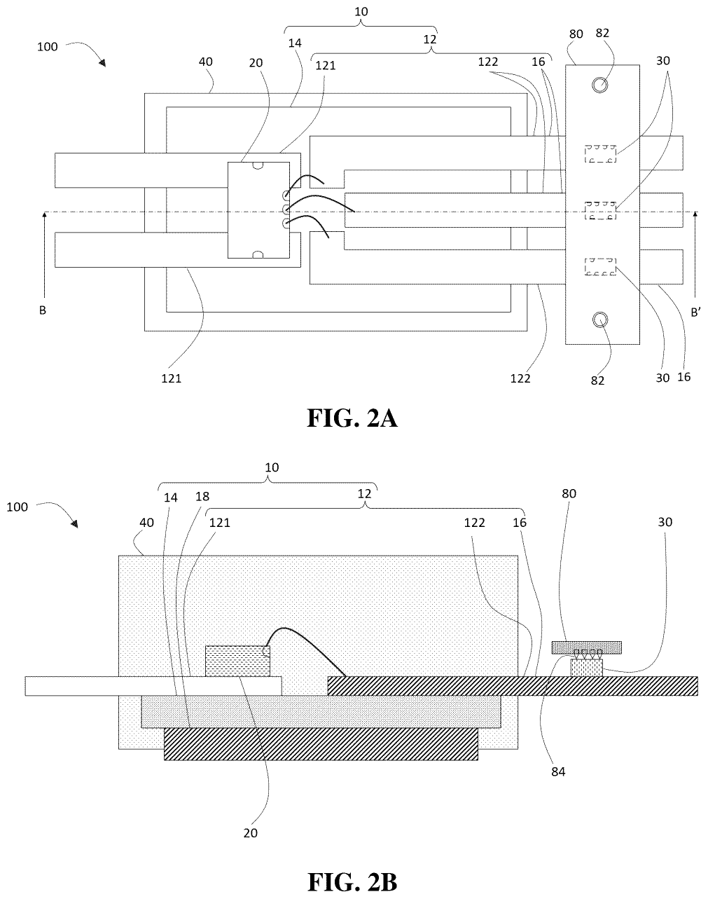

Referring to FIG. 2A and FIG. 2B, a first embodiment of the present disclosure provides a power module 100, including a leadless frame substrate (also known as lead-off substrate) 10, at least one semiconductor power device 20, a current detector 30, and a molding compound 40. The leadless frame substrate 10 includes a first metal layer 12 and an insulating layer 14. That is, the leadless frame substrate 10 is a composite material layer substrate composed of multiple material layers, wherein the first metal layer 12 forms a circuit traces (including an input terminal 121, an extension structure 122, and an output terminal 16) disposed on the insulating layer 14 and the first metal layer 12 has the extension structure 122 extending out of the insulating layer 14 to serve as the output terminal 16. The at least one semiconductor power device 20 is disposed on the first metal layer 12. The current detector 30 is disposed on the output terminal 16. The molding compound 40 completely covers part of the first metal layer 12 of the leadless frame substrate 10 on the insulating layer 14 and the at least one semiconductor power device 20, and partially covers the output terminal 16 to allow the current detector 30 completely exposed outside the molding compound 40. The power module 100 is used to convert direct current (DC) power into an alternating current (AC) power, to output the AC power through the output terminal 16, and to detect the AC power through the current detector 30.

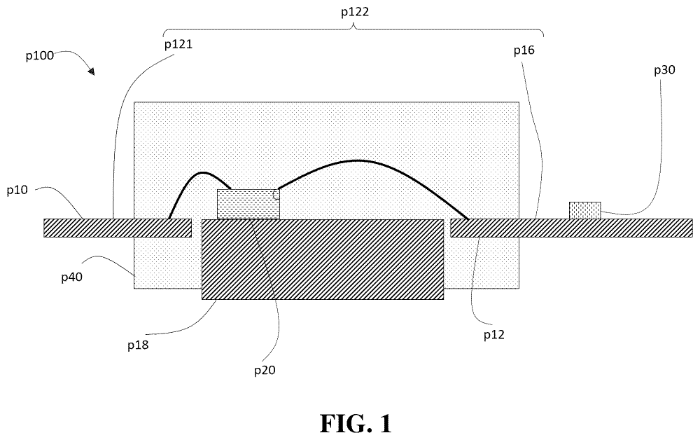

Referring to FIG. 1, a traditional power module p100 includes a lead-frame substrate, which is different from the multiple material layers (as shown in FIG. 2B) of the leadless frame substrate 10 of the present disclosure. In the conventional technology of FIG. 1, a circuit trace p12 covered by a molding compound p40 and an extension structure p122 extending out of the molding compound p40 are completely formed by a lead frame p10. The extension structure p122 is used as an input terminal p121 or an output terminal p16 of the power module. The current detector p30 is disposed on the output terminal p16. A semiconductor power device p20 is disposed on the heat sink p18. However, the lead frame p10 is manufactured by metal stamping and cannot provide the precise positioning required by the current detector of the present disclosure. The present invention uses a leadless frame substrate (also known as lead-off substrate) 10, which is mainly characterized by extending a metal surface of a composite material layer substrate out of an insulating layer and forming a connection component to serve as an input terminal or an output terminal of the power module.

Referring to FIG. 2A and FIG. 2B, in one embodiment, the leadless frame substrate (lead-off substrate) 10 is a ceramic substrate. The first metal layer 12 is, for example, made of copper or aluminum by casting and etching to form a circuit trace with high positioning and shape accuracy. Its thickness is generally between 0.5 and 0.8 mm, and can be as high as 1.2 mm. Compared with a circuit layer of a general circuit board, the first metal layer 12 is thicker and can extend out of the insulating layer 14 without underlying support of the insulating layer 14 to serve as output or input pins or plugs. The thicker first metal layer 12 can also be suitable for larger operating voltages and larger operating currents of semiconductor power devices. The insulating layer 14 is, for example, made of ceramic material having both insulating and heat-resistant properties. The leadless frame substrate 10 is suitable for use in high temperature and vibration environments in electric field. By using the leadless frame substrate 10, size of the power module can be reduced, and power density can be increased.

Referring to FIG. 2A and FIG. 2B, in one embodiment, the first metal layer 12 forms circuit traces (including an input terminal 121, an extension structure 122, and an output terminal 16) disposed on the insulating layer 14, for example, including two input terminals 121 that introduce DC potential to provide input potential required by the semiconductor power device 20, and the extension structure 122 extending out of the insulating layer 14 serves as three output terminals 16 for drawing out three-phase alternating current output by the semiconductor power device 20. Detail of circuit can be designed according to actual needs. The semiconductor power device 20 outputting three-phase alternating current is only an example. The three output terminals 16 shown in FIG. 2A are only examples. The type of AC power and the number of output terminals 16 can be designed according to requirements. The alternating current may be single-phase two-wire, single-phase three-wire, or two-phase, three-phase, four-phase, six-phase, etc., and the invention is not limited thereto.

Referring to FIG. 2A and FIG. 2B, the semiconductor power device 20 is, for example, a DC-to-AC device, which can be mount on two input terminals 121 formed by the first metal layer 12 by surface mount technology (SMT), or the semiconductor power device 20 can be electrically connected to the two input terminals 121 by bonding wires. An output terminal of the semiconductor power device 20 is electrically connected to corresponding output terminal 16 by bonding wire or SMT. The present disclosure is not limited thereto (as shown in FIG. 2A, the semiconductor power device 20 is disposed on the surface on the two input terminals 121 by SMT, and the output terminal of the semiconductor power device 20 is electrically connected to the corresponding output terminal 16 by a bonding wire). It can provide one or more semiconductor power devices 20 in a power module as required. Other electronic components may also be provided in the power module 100 as required, and this disclosure is not limited thereto.

Referring to FIG. 2A and FIG. 2B, the current detector 30 is, for example, a Hall current detector or a magneto impedance (MI) current detector. Preferably, the current detector is packaged by surface mount technology. It is suitable to use surface mount technology or die bond technology of a semiconductor chip to dispose the current detector 30 on the output terminal 16 with a robotic arm. The positioning accuracy of the current detector 30 can be significantly improved. Generally, current detectors are divided into contact type (such as Hall detector) and non-contact type (such as magneto impedance detector). The contact current detector is provided with a detection current input terminal and a detection current output terminal for allowing the current to be detected to flow into the current detector. Non-contact current detectors do not need to set detection current input terminals and detection current output terminals. The signal end of the Hall current detector is usually equipped with 4 terminals, which are a positive potential terminal and a negative potential terminal (ground) that provide working potential of the detector, as well as a signal output terminal and a reference potential terminal that output detection signal. Magneto impedance detectors generally only need a signal output terminal and a reference potential terminal. However, the present disclosure is not limited thereto, and the number of terminals of the current detector can be set according to actual requirements.

Referring to FIG. 2A and FIG. 2B, in one embodiment, the molding compound 40 includes a polymer or a resin, such as epoxy, acrylonitrile-butadiene-styrene copolymer (ABS), polycarbonate (PC), polyurethane (PU), etc., the present disclosure is not limited thereto. The molding compound 40 completely covers the portion of the first metal layer 12 located on the insulating layer 14 and the semiconductor power device 20 to protect the first metal layer 12 and the semiconductor power device 20. The mold compound 40 partially covers the output terminal 16 so that the current detector 30 is completely exposed outside the molding compound 40.

Referring to FIG. 2B, in one embodiment, in order to accurately position the current detector 30, the current detector is not first fixed on the circuit board and then fixed with the power module 100 in a traditional way. The current detector 30 is fixed on the output terminal 16 using surface mount technology or die bond technology. Then, the circuit board 80 provided with elastic pieces or clip structures 84 is crimped with the signal end of the current detector 30 for electrical connection, and the circuit board 80 is fixed through the locking hole 82. This can avoid from inaccurate positioning caused by the traditional manual fixing of the circuit board 80 and from resulting positioning differences of the current detector 30.

In a power module 100 according to an embodiment of the present disclosure, the magnetic susceptibility of the first metal layer 12 is less than 1 and greater than 0. In detail, in order to prevent from magnetization of the first metal layer 12 to cause additional impact on signal of the current detector 30 or from hysteresis to cause deviation of the signal of the current detector 30 in the future, the first metal layer 12 is preferably made of non-ferrous metal, or conductive material with a magnetic susceptibility less than 1 and greater than 0, such as copper, aluminum, etc.

Referring to FIG. 2B, in a power module 100 according to an embodiment of the present disclosure, the leadless frame substrate 10 further includes a second metal layer 18 disposed under the insulating layer 14, and the molding compound 40 partially covers the second metal layer 18. In detail, the second metal layer can be used to contact a heat sink, a heat pipe, a fan, etc. for the power module 100 to dissipate heat.

In a power module according to an embodiment of the present disclosure, the current detector 30 is fixed on the output terminal 16 with the assistance of a robot arm. In detail, the current detector 30 is fixed on the output terminal 16 with a robotic arm by surface mount technology or die bonding technology.

The principle of die bonding is to use various means such as glue, heat, pressure, or ultrasonic waves to fix the die or components on the designated material. Die bonding technology includes the following categories, such as adhesive die bonding or eutectic process. The eutectic process is further divided into thermos-compression die bonding or thermo-sonic die bonding.

Adhesive die bonding fixes a die (referred to as a current detector in this disclosure) to a substrate or material by using an adhesive material. The characteristics of the adhesive material can be electrically conductive or non-conductive. The adhesive material is taken out from the low-temperature freezer before operation and returned to normal temperature to become a liquid state. Then the adhesive material is added to the substrate or material by automatic dispensing equipment before the die is placed. After the die is placed, the substrate is placed in an oven to bake and solidify the adhesive material to complete the die bonding operation.

The eutectic process is to bond two identical or different metals to achieve electrical conduction. In this disclosure, the soldering pad on the current detector 30 package is metal bonded with the first metal layer. The thermos-compression die bonding process provides heat energy to the solder layer to cause the solder to melt into a liquid state. The other soldering point provides in a temperature just below the melting point of the solder. The liquefied solder contacts the metal of the other bonding surface to form a metal bond (intermetallic bond), also known as wetting. In order to avoid object displacement caused by liquid solder, when two objects are combined, pressure can be applied to fix the soldered objects. Using flux can increase the optimal metal bonding. The most common solder currently used in the industry during the thermos-compression die bonding process is made of gold-tin.

The thermo-sonic die bonding uses mechanical ultrasonic vibration to provide energy to combine two metals. The most used metals are gold-to-gold. Generally, thermos-compression die bonding process requires temperature above 270° C. The high temperature can easily cause damage to the substrate or some sensitive chips. The thermo-sonic die bonding significantly reduces the die-bonding temperature to less than 150° C. and does not require the use of flux and post-soldering cleaning procedures.

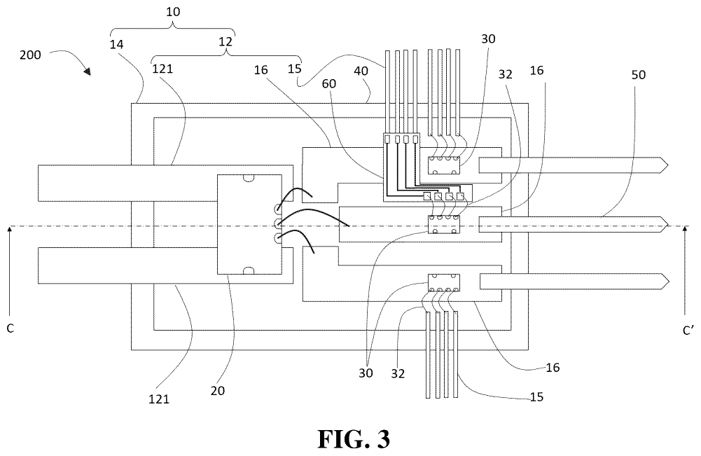

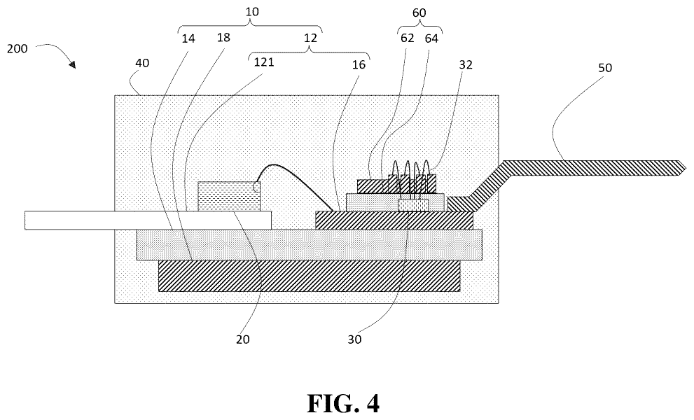

Referring to FIG. 3 and FIG. 4, a second embodiment of the present disclosure provides a power module 200, including: a leadless frame substrate (lead-off substrate) 10 including a first metal layer 12 and an insulating layer 14, wherein the first metal layer 12 forms a circuit trace (including an input terminal 121, a signal pin 15, and an output terminal 16) disposed on the insulating layer 14; at least one semiconductor power device 20 disposed on the circuit trace (including the input terminal 121); a current detector 30 disposed on the output terminal 16; and a molding compound 40 completely covers the first metal layer 12 of the leadless frame substrate 10, the at least one semiconductor power device 20, and the current detector 30. The power module 200 is used to convert DC power into AC power, to output the AC power through the output terminal 16, and to detect the AC power by the current detector 30.

Referring to FIG. 3 and FIG. 4, the power module 200 is similar to the power module 100, with the main difference being that the molding compound 40 of the power module 200 completely covers the current detector 30. For other components similar to the power module 100, please refer to the corresponding paragraphs above and the descriptions of FIG. 2A and FIG. 2B. They will not be described again. The molding compound 40 of the power module 200 completely covers the current detector 30 to provide structural and positional protection of the current detector 30.

Referring to FIG. 3 and FIG. 4, in the power module 200 according to the second embodiment of the present disclosure, the magnetic susceptibility of the first metal layer 12 is less than 1 and greater than 0. In the power module 200 according to an embodiment of the present disclosure, the leadless frame substrate 10 further includes a second metal layer 18 disposed under the insulating layer 14, and the molding compound 40 partially covers the second metal layer 18. In the power module 200 according to an embodiment of the present disclosure, the current detector 30 is fixed on the output terminal 16 with the assistance of a robot arm.

Referring to FIG. 3 and FIG. 4, the power module 200 according to the second embodiment of the present disclosure further includes a lead frame 50 connected to the output terminal 16. In detail, in this embodiment, the output terminal 16 does not protrude from the molding compound 40, and the lead frame 50 is instead welded on the output terminal 16 to provide power output. Both the positioning accuracy of the current detector 30 and the structural strength of the lead frame 50 can be maintained. The lead frame 50 can be electrically connected to the output terminal 16 and fixed on the output terminal 16 by welding or sintering.

Referring to FIG. 3 and FIG. 4, in one embodiment, the power module 200 further includes a signal pin 15 formed by the first metal layer 12 for electrically connecting the signal ends of the current detector 30. FIG. 3 and FIG. 4 show that bonding wires 32 are used to connect the signal ends of the current detector 30 with the signal pins 15, but the present disclosure is not limited thereto. In other embodiment, the signal ends of the current detector 30 is connected to the signal pin 15 by SMT method.

Referring to FIG. 3 and FIG. 4, in one embodiment, the power module 200 further includes a ceramic substrate, such as a multilayer substrate circuit structure 60 disposed on the first metal layer 12. The multilayer substrate circuit structure 60 is, for example, a direct bonded copper substrate (DBC, also known as a copper-clad ceramic substrate) or an active metal brazing (AMB) substrate, both of which are ceramic substrates. The multilayer substrate circuit structure combines heat dissipation of ceramics and conductor properties of metal. After a copper foil is oxidized, the thick copper foil is directly covered on a ceramic substrate using high-temperature sintering, and then the circuit pattern is carved on the copper foil through photolithography (exposure and development). The multilayer substrate circuit structure 60 can be provided with multiple metal layers 62 and multiple ceramic layers 64 staggered and overlapped. FIG. 4 only illustrates one metal layer 62 and one ceramic layer 64 for example. However, it is not limited thereto. The ceramic layer 64 can also form perforations to provide electrical connection between the upper and lower metal layers 62. The connection method between the signal end of the current detector 30 and the signal pin 15 of the power module 200 uses the bonding wires 32 to connect the signal ends of the current detector 30 with the metal layer 62 on the multilayer substrate circuit structure 60, and then the multilayer substrate circuit structure 60 (for example, via interconnections in through holes of the ceramic layer 64, not shown) is connected to the signal pins 15.

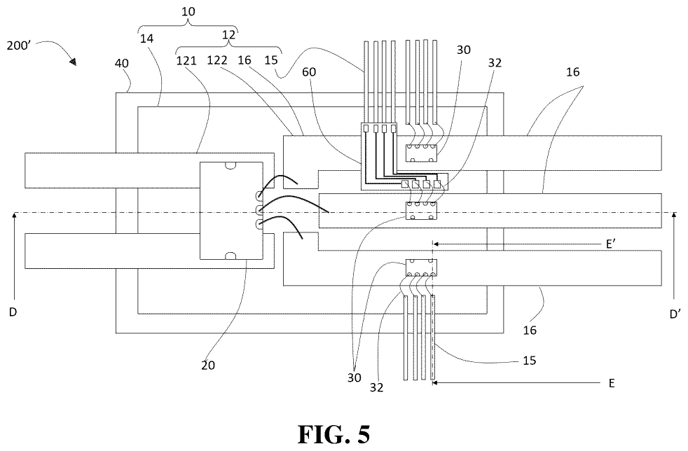

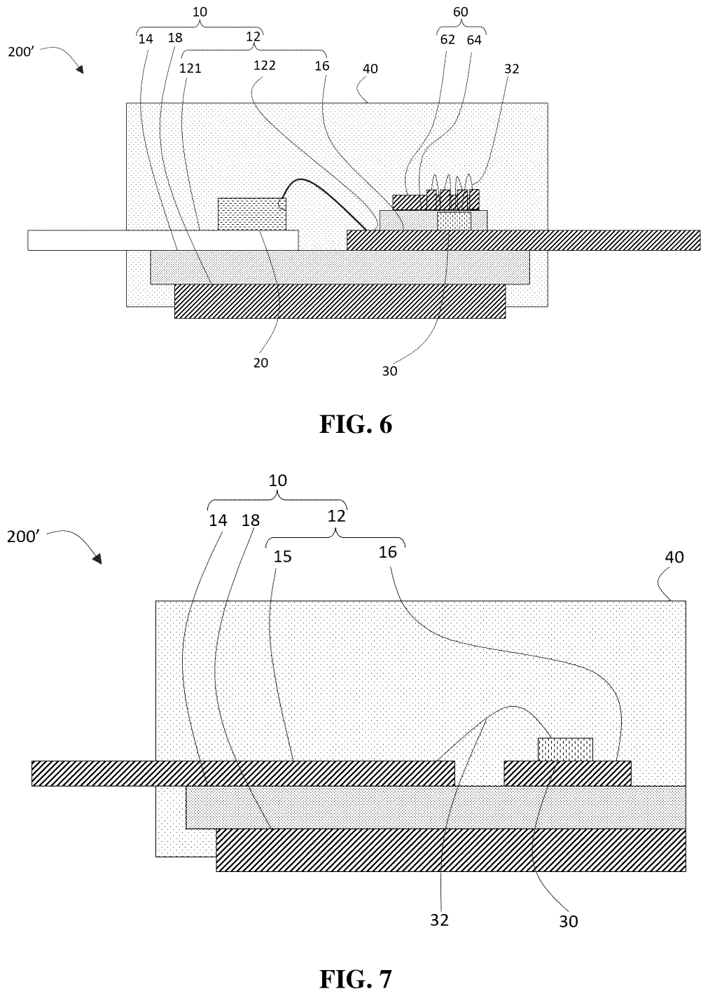

Referring to FIG. 5, FIG. 6, and FIG. 7, the difference between the power module 200′ of the third embodiment of the present disclosure and the power module 200 is that the power module 200′ is not provided with a lead frame 50, and the output terminal 16 is directly extended from the molding compound 40. For example, the first metal layer 12 includes an extension structure 122 extending out of the insulating layer 14 to serve as an output terminal 16. In different embodiments, an output terminal portion 16 formed by a thickened first metal layer 12 has sufficient strength to form a pin or plug for power output. For other components similar to the power modules 100 and 200, please refer to the corresponding paragraphs above and the descriptions of FIG. 2A to FIG. 4. They will not be described again.

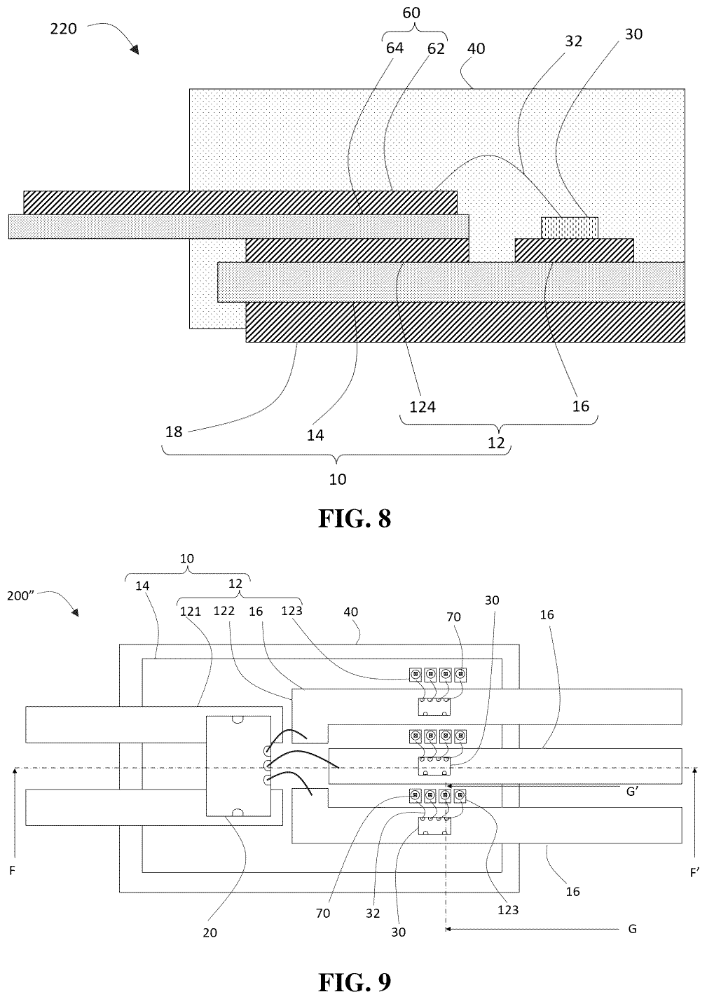

Referring to FIG. 8, the power module 220 according to the fourth embodiment of the present disclosure is different from the power module 200′ in that the signal pins 15 in the power module 200′ is replaced to a multilayer substrate circuit structure 60 in the power module 220. The current detector 30 is electrically connected to the metal layer 62 of the multilayer substrate circuit structure 60 through bonding wires 32. In addition to the strong structural strength of the ceramic layer 64, the multilayer substrate circuit structure 60 can be suitable for more complex circuit designs. For other components similar to the power modules 100, 200, or 200′, please refer to the corresponding paragraphs above and the descriptions of FIG. 2A to FIG. 7. They will not be described again.

Referring to FIG. 8, the power module 220 according to the fourth embodiment of the present disclosure further includes a multilayer substrate circuit structure 60 disposed on the circuit traces 124 of the first metal layer 12. In the power module 220 according to an embodiment of the present disclosure, the multilayer substrate circuit structure 60 extends outside the molding compound 40, and the signal end of the current detector 30 is electrically connected to the multilayer substrate circuit structure 60 via bonding wires 32.

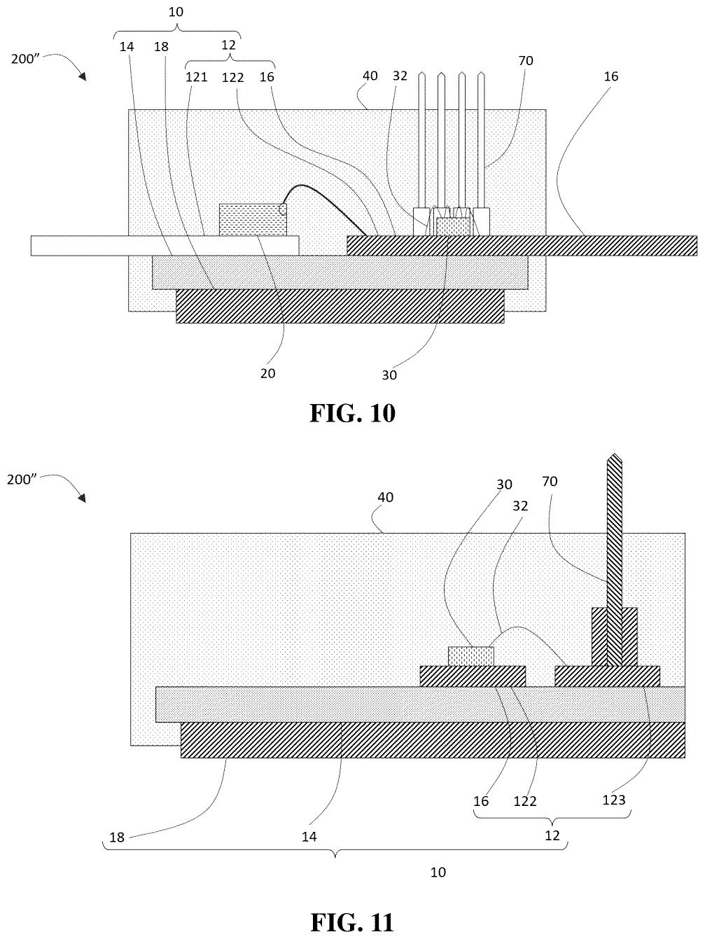

Referring to FIG. 9, FIG. 10, and FIG. 11, the difference between the power module 200″ according to the fifth embodiment of the present disclosure and the power module 200′ is that the power module 200″ has a pin structure 70 provided on the first metal layer 12 to replace the signal pins 15 of the power module 200′. The current detector 30 is a surface mount device (SMD), and the signal end of the current detector 30 is electrically connected to the pin structure 70 through circuit traces 123. For other components similar to the power modules 100, 200, 200′, and 220, please refer to the corresponding paragraphs above and the descriptions of FIG. 2A to FIG. 8. They will not be described again.

Referring to FIG. 9, FIG. 10, and FIG. 11, the signal end of the current detector 30 is connected to the circuit trace 123 of the first metal layer 12 through bonding wires 32, and then is electrically connected to the pin structure 70 provided on the circuit trace 123.

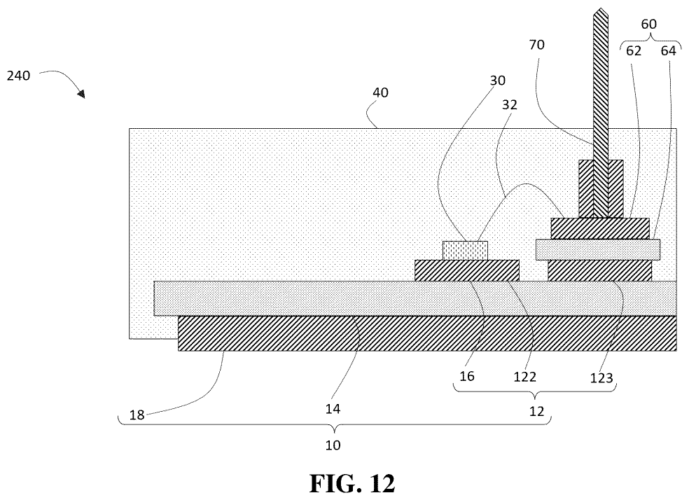

Referring to FIG. 12, the difference between the power module 240 according to the sixth embodiment of the present disclosure and the power module 200″ is that the pin structure 70 of the power module 240 is disposed on a multilayer substrate circuit structure 60. The signal end of the current detector 30 is electrically connected to the metal layer 62 of the multilayer substrate circuit structure 60 through bonding wires 32 and is electrically connected to the pin structure 70 through the multilayer substrate circuit structure 60. For other elements similar to 100, 200, 200′, 220, 200″, please refer to the corresponding paragraphs above and the descriptions of FIG. 2A to FIG. 11. They will not be described again.

In comparison with prior art, the disclosed structure of the power module is suitable for precise packaging technologies such as surface mount technology (SMT), which can accurately install the current detector at the output terminal to provide a power module with a current detector. Because the positioning error of the current detector disclosed in the present disclosure is small, an initial calibration data of the sensing signal can be directly applied to each power module, and there is no need to recalibrate the signal of the current detector of each power module to effectively avoid the issue in the prior art.

The above are only preferred embodiments of the present disclosure, and it should be pointed out that for those of ordinary skill in the art, without departing from the principle of the present disclosure, some improvements and modifications can also be made, and these improvements and modifications should also be regarded as protection scope of this disclosure.

What is claimed is:

1. A power module, comprising:
a leadless frame substrate including a first metal layer and an insulating layer, wherein the first metal layer forms a circuit trace disposed on the insulating layer and the first metal layer comprises an extension structure extending out of the insulating layer to serve as an output terminal;
at least one semiconductor power device disposed on the first metal layer;
a current detector disposed on the output terminal; and
a molding compound, completely covering part of the first metal layer disposed on the insulating layer and the at least one semiconductor power device, and partially covering the output terminal so that the current detector is completely disposed outside the molding compound, wherein the power module is configured to convert a direct current power to an alternating current power, to output the alternating current power through the output terminal, and to detect the alternating current power by the current detector.

2. The power module according to claim 1, wherein a magnetic susceptibility of the first metal layer is less than 1 and greater than 0.

3. The power module according to claim 1, wherein the leadless frame substrate further comprises a second metal layer disposed under the insulating layer and the molding compound partially covers the second metal layer.

4. The power module according to claim 1, wherein the current detector is disposed on the output terminal with an assistance of a robot arm.

5. A power module, comprising:
a leadless frame substrate including a first metal layer and an insulating layer, wherein the first metal layer forms a circuit trace disposed on the insulating layer and comprising an output terminal;
at least one semiconductor power device disposed on the circuit trace;
a current detector disposed on the output terminal; and
a molding compound, completely covering the first metal layer of the leadless frame substrate, the at least one semiconductor power device, and the current detector, wherein the power module is configured to convert a direct current power to an alternating current power, to output the alternating current power through the output terminal, and to detect the alternating current power by the current detector.

6. The power module according to claim 5, wherein a magnetic susceptibility of the first metal layer is less than 1 and greater than 0.

7. The power module according to claim 5, wherein the leadless frame substrate further comprises a second metal layer disposed under the insulating layer and the molding compound partially covers the second metal layer.

8. The power module according to claim 5, wherein the current detector is disposed on the output terminal with an assistance of a robot arm.

9. The power module according to claim 5, further comprising a lead frame connected to the output terminal.

10. The power module according to claim 5, further comprising a pin structure disposed on the first metal layer, wherein the current detector is of a surface mount device and a signal end of the current detector is electrically connected to the pin structure through the circuit trace.

11. The power module according to claim 5, wherein a signal end of the current detector is electrically connected to the first metal layer through a bonding wire.

12. The power module according to claim 5, further comprising a multilayer substrate circuit structure disposed on the first metal layer.

13. The power module according to claim 12, wherein the multilayer substrate circuit structure extends outside the molding compound and a signal end of the current detector is electrically connected to the multilayer substrate circuit structure through a bonding wire.

14. The power module according to claim 12, further comprising a pin structure disposed on the multilayer substrate circuit structure, wherein a signal end of the current detector is electrically connected to the multilayer substrate circuit structure through bonding wire and is further electrically connected to the pin structure through the multilayer substrate circuit structure.
